(19) United States
(12) Patent Application Publication
(10) Pub. No.: US 2014/0312439 A1
(43) Pub. Date: Oct. 23, 2014

(54) Microphone Module and Method of Manufacturing Thereof

(71) Applicant: INFINEON TECHNOLOGIES AG, Neubiberg (DE)

(72) Inventors: Juergen Hoegerl, Regensberg (DE); Horst Theuss, Wenzenbach (DE)

(21) Appl. No.: 13/866,084

(22) Filed: Apr. 19, 2013

(51) Int. Cl. B81B 7/00; B81C 1/00

(52) U.S. Cl. CPC B81B 7/0077; B81C 1/00333
USPC 257/416; 438/51

(57) ABSTRACT

A microphone module includes a package including a semiconductor chip and having a recess on an upper surface and a micro-electro-mechanical microphone being electrically connected to the package. Further, the micro-electro-mechanical microphone is arranged on the upper surface of the package. The recess forms an acoustic back volume of the micro-electro-mechanical microphone.

### TECHNICAL FIELD

The disclosure relates to electronic modules and assemblies and more particularly to modules and assemblies including micro-electro-mechanical microphones.

### BACKGROUND

Semiconductor device manufacturers are constantly striving to increase the versatility and performance of their products, while decreasing their cost of manufacture. An important component of the manufacturing process of semiconductor devices is packaging the devices. One component that may be included in semiconductor device packaging is a micro-electro-mechanical microphone. Typically, such a micro-electro-mechanical microphone is mounted in a casing that typically comprises semiconductor chip. Micro-electro-mechanical microphones packaged like this are used to transform sound into electrical signals in applications that require smaller sized components. Accordingly, packaging methods providing high performance devices at low expenses and having small dimensions are desirable.

### SUMMARY

According to an embodiment, a microphone module is provided. The microphone module includes a package body having a recess on an upper surface, a semiconductor chip embedded in the package body, and a micro-electro-mechanical microphone chip including an electro-mechanical element arranged over the recess and electrically connected to the semiconductor chip.

According to another embodiment, a microphone module assembly is provided. The microphone module assembly includes an encapsulant including an array of recesses on an upper surface, and an array of semiconductor chips embedded in the encapsulant, wherein each semiconductor chip is associated with a recess. The microphone module assembly further includes an array of micro-electro-mechanical microphone structures, wherein each micro-electro-mechanical microphone structure includes an electro-mechanical element arranged over one of the recesses and is electrically connected to the semiconductor chip associated with the respective recess.

According to another embodiment, a method of producing a microphone module is provided. The method includes providing a package body having a recess on an upper surface and including a semiconductor chip and providing a micro-electro-mechanical microphone chip including an electro-mechanical element. The method further includes arranging the micro-electro-mechanical microphone chip over the upper surface of the package body and electrically connecting the micro-electro-mechanical microphone chip to the package body such that the recess forms an acoustic back volume of a micro-electro-mechanical microphone.

According to another embodiment, a method of producing a microphone module is provided. The method includes forming an encapsulant having an array of recesses on an upper surface thereof and an array of semiconductor chips embedded therein and arranging an array of micro-electro-mechanical microphone structures over the encapsulant, wherein each micro-electro-mechanical microphone structure includes an electro-mechanical element arranged over a recess. The method further includes electrically connecting each of the plurality of micro-electro-mechanical microphone structures to a semiconductor chip associated with the respective recess and separating the encapsulant into single package bodies, each package body including one of the recesses and one of the semiconductor chips.

### BRIEF DESCRIPTION OF THE DRAWINGS

The accompanying drawings are included to provide a further understanding of embodiments and are incorporated in and constitute a part of this specification. The drawings illustrate embodiments and together with the description serve to explain principles of embodiments. Other embodiments and many of the intended advantages of embodiments will be readily appreciated, as they become better understood by reference to the following detailed description. The elements of the drawings are not necessarily to scale relative to each other. Like reference numerals designate corresponding similar parts.

FIG. 1 schematically illustrates a cross-sectional view of an exemplary microphone module.

FIG. 2 schematically illustrates a cross-sectional view of an exemplary microphone module.

FIG. 3 schematically illustrates a cross-sectional view of an exemplary microphone module.

FIG. 4 schematically illustrates a cross-sectional view of an exemplary microphone module.

FIG. 5 schematically illustrates a cross-sectional view of an exemplary microphone module.

FIG. 6 schematically illustrates a cross-sectional view of an exemplary microphone module.

FIG. 7 schematically illustrates a cross-sectional view of an exemplary microphone module.

FIGS. 8, 9, 10, and 11 schematically illustrate cross-sectional views of an exemplary process of a method of manufacturing a microphone module.

### DETAILED DESCRIPTION

In the following detailed description, reference is made to the accompanying drawings, which form a part thereof, and in which is shown by way of illustration specific embodiments in which the invention may be practiced. In this regard, directional terminology, such as “top”, “bottom”, “left”, “right”, “upper”, “lower” etc., is used with reference to the orientation of the Figure(s) being described. Because components of embodiments can be positioned in a number of different orientations, the directional terminology is used for purposes of illustration and is in no way limiting. It is to be understood that other embodiments may be utilized and structural or logical changes may be made without departing from the scope of the present invention. The following detailed description, therefore, is not to be taken in a limiting sense, and the scope of the present invention is defined by the appended claims.

It is to be understood that the features of the various exemplary embodiments described herein may be combined with each other, unless specifically noted otherwise or unless technically restricted.

As employed in this specification, the terms “bonded”, “attached”, “connected”, “coupled” and/or “electrically coupled” are not meant to mean that the elements must directly be contacted together; intervening elements or layers may be provided between the “bonded”, “attached”, “connected”, “coupled” and/or “electrically coupled” elements, respectively.

Microphone modules and assemblies described in the following include embodiments of a micro-electro-mechanical microphone which dynamically transforms sound, e.g., in the audible frequency range into electrical signals in combination with a package comprising a semiconductor chip.

The microphone modules include a package body that has a recess on an upper surface thereof. The recess may be formed in a part of the package body made of plastic, which can be manufactured by various techniques, among them molding techniques like compression molding or injection molding, or by machining techniques such as milling. These techniques may provide for both high design variability and low cost production. The recess may form an acoustic back volume of the micro-electro-mechanical microphone.

Metal structures that serve as contact elements for electronic components of the package or establish conduction paths may be generated over the surface of the package body. Different techniques are available to generate such metal structures on the package body, such as: A galvanic or electroless plating process, physical vapor deposition (PVD), chemical vapor deposition (CVD), sputtering, spin-on processes, spray deposition or printing such as, e.g., ink-jet printing may be employed to form such conductive or metal structures.

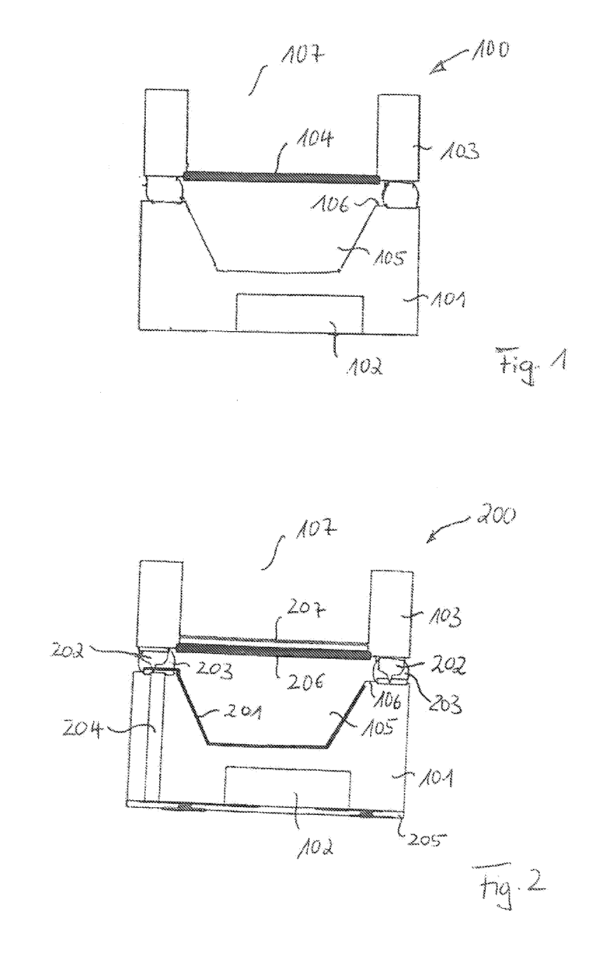

FIG. 1 illustrates an embodiment of a microphone module 100. Microphone module 100 includes a package body 101 embedding a semiconductor chip 102 and having a recess 105 at an upper surface 106 thereof. Further, microphone module 100 comprises a micro-electro-mechanical microphone chip 103. The package body 101 may comprise or be made of a polymer material that may be manufactured by a molding technique or by a lamination technique. The polymer material may e.g., be a resin, epoxy, acrylate or polyimide material. Specific examples of materials that may be used for the polymer material are PEEK (polyetheretherketone), PPS (polyphenylsulphone), PSU (polysulfone), PEI (polyetherimide), PAI (polyamidimide) and LCP (liquid crystalline polymers).

The micro-electro-mechanical microphone chip 103 may be made from a semiconductor material e.g., silicon, and is able to transform sound into an electrical signal. The micro-electro-mechanical microphone chip 103 may also be made from an insulating material e.g., glass, plastics, etc. The micro-electro-mechanical microphone chip 103 may be arranged over the upper surface 106 of the package body 101 and may be mechanically connected thereto by appropriate means e.g., bonding, gluing, clamping, etc. The micro-electro-mechanical microphone chip 103 can be mounted in a face-down orientation, which is also known as “flip-chip mounted”, relative to the package body 101.

The micro-electro-mechanical microphone chip 103 includes an electro-mechanical element 104. The electro-mechanical element 104 may comprise a mechanical element (not shown in detail in FIG. 1) which acts upon forces such as acoustical waves, and may further comprise an electronic element (not shown in detail in FIG. 1), such as a capacitor, to generate an electrical signal modulated according to the actuation of the mechanical element. The electro-mechanical element 104 may be exposed to sound waves via an opening 107 of the micro-electro-mechanical microphone chip 103. The recess 105 may be located below the electro-mechanical element 104 and forms an acoustic back volume of the micro-electro-mechanical microphone.

In FIGS. 2-11, the same reference numerals designate like or similar parts as previously described with reference to FIG. 1. Further, reference is made to the corresponding description to avoid reiteration. FIG. 2 illustrates a microphone module 200 in more detail than the illustration of module 100 in FIG. 1. The package body 101 may e.g., comprise a through-contact 204, shown on the left side of the package body 101 in the embodiment of FIG. 2. The through-contact 204 may run through the entire package body 101, i.e. may provide an electrical connection between the upper surface of the package body 101 and a lower surface of the package body 101. A second through-contact (not shown) may be arranged at the right side of the recess 105. There may be more electrical contacts extending between the upper surface of the package body 101 and the lower surface thereof, for instance via through-contacts as exemplified by through-contact 204, or by other means. For example, a quantity of 2, 3, 4, 5 or more through-contacts 204 may be provided.

An electrical connection between the micro-electro-mechanical microphone chip 103 and the package body 101 may be provided by depositing, e.g., printing, an anisotropic conductive paste (ACP) onto the package body 101. The ACP may be deposited on an electrical structure such as through-contact 204. In a subsequent assembly, the micro-electro-mechanical microphone chip 103 may be placed onto the package body 101, e.g., with flip-chip electrodes facing the electrical structures. The ACP may also provide for a mechanical fixture of the micro-electro-mechanical microphone chip 103 to the package body 101 and for an acoustic seal.

In some embodiments, a non-conductive paste (NCP) may be deposited onto the package body 101. In this case, the micro-electro-mechanical microphone chip 103 may be equipped with electrically conducting deposits 202, such as solder deposits or studbumps. These conducting deposits 202 may be used to electrically and, optionally, mechanically interconnect the micro-electro-mechanical microphone chip 103 to the package body 101. For example, if the conducting deposits 202 are formed as studbumps, the studbumps of the micro-electro-mechanical microphone chip 103 may be pressed into the NCP on the upper surface of the package body 101. This may result in an electrical interconnect between the studbumps and a metal pad on the package body 101, thus providing an electrical connection between the package body 101 and the micro-electro-mechanical microphone chip 103. Further, this may provide an additional mechanical fixture of the micro-electro-mechanical microphone chip 103 to the package body 101.

An acoustic seal 203 may be arranged between the package body 101 and the micro-electro-mechanical microphone chip 103. Such an acoustic seal 203 may provide an air tight closure of the recess 105 by the micro-electro-mechanical microphone chip 103. As a result, a complete protection against the environment, for instance against dust, dirt, moisture, etc. may be obtained.

The microphone module 200 may comprise an electrically conducting shielding layer 201 arranged on the upper surface of the package body 101. The shielding layer 201 may be a metal layer. Furthermore, the shielding layer 201 may be an overall plating, covering the entire upper surface of the package body 101, except specific areas where contacts, such as the through-contacts 204 described above, are located. For example, the shielding layer 201 may at least entirely cover the upper surface of the package body 101 as defined by the recess 105.

The shielding layer 201 may be applied by an additive or subtractive plating process. In addition, the shielding layer 201 may be applied as a foil, having a thickness of several tens to several hundreds of micrometers. The shielding layer 201 may be a metal foil attached to the package 101 by an adhesive. Alternatively, the shielding layer 201 may itself be a conductive adhesive. Further, the shielding layer 201 may be applied by a plating process e.g., galvanic plating or electroless plating. If a galvanic plating process is used, a seed layer (not shown) may be deposited onto the upper surface of the package body 101. The seed layer may be made of zinc. The seed layer is employed as an electrode, and copper or other metals or metal alloys may then be plated onto the seed layer to the desired height. Alternatively, electroless plating may be used to generate the shielding layer 201. Electroless plating is also referred to as chemical plating in the art. Still further, other deposition methods such as printing, sputtering, spin coating, etc., may be used. Finally, shielding layer 201 may be applied by metal foil lamination.

The package body 101 may comprise a lower surface opposite to the upper surface. The lower surface of the package body 101 may level with a lower surface of the semiconductor chip 102. The lower surface of the package body 101 and, if lying in the same plane, the lower surface of the semiconductor chip 102, may be covered by an electrical redistribution structure 205.

The electrical redistribution structure 205 may comprise an electrically conducting rewiring layer for providing electrical connections to other components. The electrical redistribution structure 205 or, more particularly, one or more rewiring layer(s) contained therein may provide electrical connection between contact pads of the semiconductor chip 102 and the through-contacts 204. The electrical redistribution structure 205 or, more particularly, the rewiring layer(s) may provide electrical connection between contact pads of the semiconductor chip 102 and external terminals of the microphone module 200, such as terminal wires protruding over the package body 101 or external terminal pads exposed at the package body 101 periphery. The electrical redistribution structure 205 or, more particularly, the rewiring layer(s) thereof may provide electrical connection(s) between the micro-electro-mechanical microphone chip 103 (e.g., via through-contacts 204 connecting thereto) and external terminal(s) of the microphone module 200, such as terminal wires protruding over the package body 101 or external terminal pads exposed at the package body 101 periphery.

The micro-electro-mechanical microphone chip 103 may comprise a first and a second thin layer 206, 207 covering the recess 105. The first and the second thin layer 206, 207 may form the electro-mechanical element 104. Sound can pass through the opening 107 in the micro-electro-mechanical microphone chip 103, which is an acoustic aperture, to reach the first thin layer 206. The first thin layer 206 may be a membrane 206 of the micro-electro-mechanical microphone chip 103. The membrane 206 may be very thin. According to various embodiments, the membrane is less than 1000 nm, 500 nm, 300 nm, or thinner. The membrane 206 may be made of silicon or metal or glass coated by metal. The micro-electro-mechanical microphone chip 103 may further be equipped with a counter electrode 207 forming the second thin layer 207. The counter electrode 207 may be driven at a voltage different to the voltage of the membrane 206. The counter electrode 207 may also be made of silicon or metal or glass coated by metal. The counter electrode 207 may have a plurality of through holes (not illustrated) to let the sound pass through.

The semiconductor chip 102 embedded in the package body 101 may be an integrated circuit (IC) such as, a logic chip or an application specific integrated circuit (ASIC). It may contain electronic components such as, filters, comparators, amplifiers, time delayers, equalizers, logic elements, memory devices or analog-to-digital converters (ADCs). It may be an analog device that only processes analog signals. It may be a conversion device that transforms analog signals of the micro-electro-mechanical microphone 103 to digital signals, or it may be designed as a mixed signal circuitry. In the case that the integrated circuit is an exclusively digital circuit or a mixed signal circuit, the frequency response of the micro-electro-mechanical microphone 103 can be equalized by implementing digital filters in the integrated circuit. In the case that an analog device is used, additional discrete non-active components (not illustrated) may be provided for signal shaping.

The dimensions of the microphone module 100 (or any other module 200-700 disclosed herein) may vary over wide ranges. In the following, X and Y denote lateral directions in a horizontal plane and Z refers to a (vertical) direction normal to X and Y. According to an embodiment, the recess 105 may have a depth measured in direction Z between the bottom surface of the recess 105 and the upper surface 106 of the package body 101 equal to or greater than, e.g., 50 μm, 80 μm, 100 μm, 200 μm, 300 μm. On the other hand, the depth may be equal to or less than, e.g., 300 μm, 200 μm, 100 μm, 80 μm, 50 μm.

The distance in the Z-direction between the lower surface of the package body 101 and the bottom surface of the recess may, be equal to or greater than, e.g., 50 μm, 75 μm, 100 μm, 150 μm, 200 μm. Alternatively, the distance in the Z-direction may be equal to or less than, e.g., 200 μm, 150 μm, 100 μm, 75 μm, 50 μm. The total height of the microphone module 100 (or any other module 200-700 disclosed herein) including the package body 101 and the micro-electro-mechanical microphone chip 103 attached thereto may be equal to or greater than, e.g., 100 μm, 200 μm, 300 μm, 400 μm, 500 μm. Alternatively, the total height of the microphone module 100 may be equal to or less than, e.g., 500 μm, 400 μm, 300 μm, 200 μm, 100 μm.

The package body 101 may have a lateral dimension or width that may be equal to or greater than, e.g., 1 mm, 2 mm, 5 mm, 10 mm. Further, the width may be equal to or less than, e.g., 10 mm, 5 mm, 2 mm, 1 mm. The width may be measured in direction X and/or Y.

The micro-electro-mechanical microphone chip 103 may have a lateral dimension or width that may be equal to or less than the lateral dimension of the package body 101. In particular, the micro-electro-mechanical microphone chip 103 may have at least one lateral dimension equal to the corresponding lateral dimension of the package body 101. In particular, equal lateral dimension(s) of the package body 101 and the micro-electro-mechanical microphone chip 103 may be obtained if, for instance, the microphone module 100 is manufactured by an eWLP (embedded Wafer Level Packaging) process as will be described in more detail further below.

The width of the microphone module 100 may be defined by the maximum lateral dimension of the package body 101 or the maximum lateral dimension of the micro-electro-mechanical microphone chip 103. In particular, the width of the microphone module 100 may, e.g., correspond to the maximum lateral dimension of the package body 101.

As depicted in the embodiment of FIG. 1, the lateral dimension of the package body 101 and the micro-electro-mechanical microphone chip 103 in one (e.g. X) or two (e.g. X,Y) lateral directions may also be equal. As will be explained in further detail below, equal lateral dimensions of the micro-electro-mechanical microphone 103 and the package 101 in one or two lateral dimensions may be obtained in the case that the microphone module 100 is cut out of a multi-device array (see FIGS. 8 to 11).

As will be explained in further detail below, the microphone module 100 and/or the microphone module 200 may be designed to include variations and/or additional details. All of the details explained by way of example in the following could be combined with the microphone module 100 or the microphone module 200 unless it is expressly stated to the contrary or such a combination is impossible due to technical restrictions.

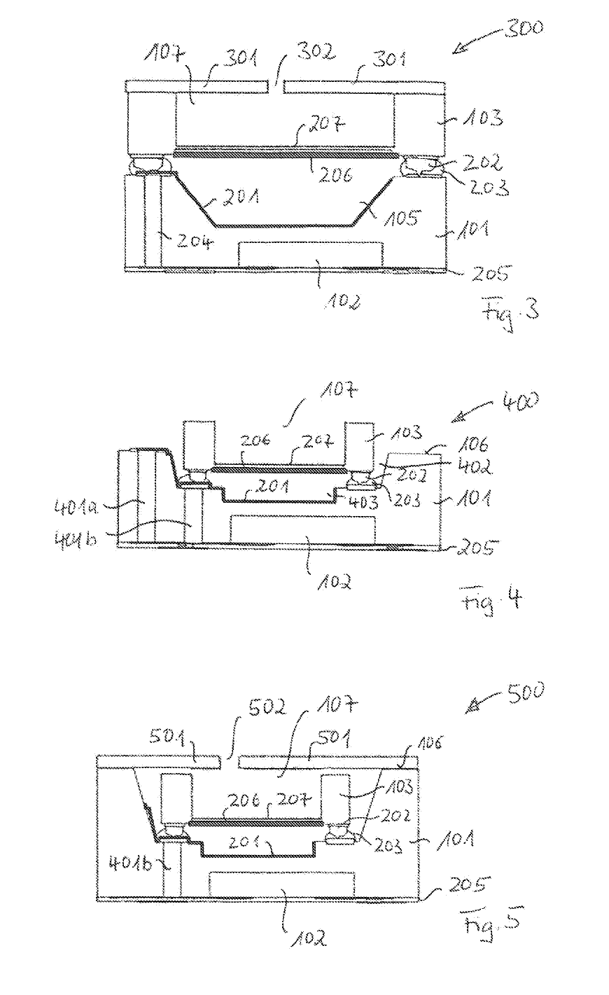

FIG. 3 illustrates a microphone module 300. In addition to the microphone module 200, the microphone module 300 comprises an additional lid 301 which may cover the opening 107. The lid 301 may comprise or consist of a polymer which can be made of materials such as, a molded polymer, prefabricated parts such as, a polymer foil, or of a thermosetting plastic. To electrically shield the micro-electro-mechanical microphone chip 103, the lid 301 may, e.g., be coated with a metal layer (not illustrated) or filled with metal particles or it can be made of a metal or a metal alloy. The lid 301 includes an acoustic aperture 302 to let the sound pass through. The thickness of the lid 301 may, e.g., be in a range between approximately 0.1 to 0.3 mm.

FIG. 4 illustrates a microphone module 400. In this exemplary microphone module 400, the lateral dimensions of the micro-electro-mechanical microphone chip 103 are smaller than the lateral dimensions of the package body 101. The package body 101 comprises a cascading recess 402, 403 comprising a lower level recess 403 and a higher level recess 402. The micro-electro-mechanical microphone chip 103 is arranged within the subjacent or higher level recess 402. The lower level recess 403 may define the acoustic back volume of the microphone. The micro-electro-mechanical microphone chip 103 may protrude over the upper surface 106 of the package body 101. The micro-electro-mechanical microphone chip 103 may optionally be closed by a lid (not shown) similar to FIG. 3. As may be seen, the semiconductor chip 102 may be arranged slightly off-centered relative to the recess 402, 403 in the package body 101. Alternatively the recess 402, 403 in the package body may also be arranged in the center thereof.

The package body 101 may comprise several through-contacts 401a, 401b. In the microphone module 400 illustrated in FIG. 4, either a through-contact 401a extending to the higher level recess 402 or a through-contact 401b extending to the lower level recess 403 or both types of through-contacts 401a, 401b may be used for connecting the micro-electro-mechanical microphone chip 103 to the periphery of the package body 101, e.g., to the electrical redistribution structure 205.

FIG. 5 illustrates an exemplary microphone module 500. Microphone module 500 is similar to microphone module 400, and reference is made to the description above to avoid reiteration. The microphone module 500 comprises a lid 501. The lid 501 may be made of materials such as, a molded polymer, prefabricated parts such as, a polymer foil, or of a thermosetting plastic. To electrically shield the micro-electro-mechanical microphone chip 103, the lid 501 may be coated e.g., with a metal layer (not illustrated), filled with metal particles, or made of a metal or a metal alloy. The lid 501 includes an acoustic aperture 502 to let the sound pass through. The lid 501 may be arranged on the side walls of the package body 101 instead on the micro-electro-mechanical microphone chip 103 as shown in FIG. 3. Similar to lid 301, the thickness of the lid 501 may, e.g., be in a range between about 0.1 to 0.3 mm. In contrast to the arrangement shown in FIG. 4, the micro-electro-mechanical microphone chip 103 may, e.g., not protrude over the upper surface 106 of the package body 101. The lid 501 may extend over the micro-electro-mechanical microphone chip 103.

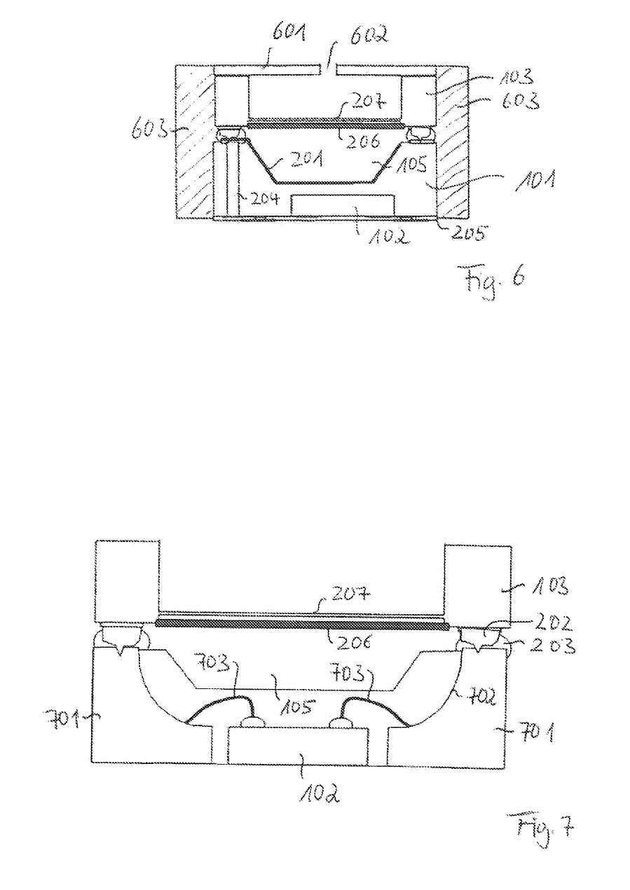

FIG. 6 illustrates an exemplary microphone module 600. The microphone module 600 is similar to the microphone module 200, and reference is made to the description above to avoid reiteration. In addition to the microphone module 200, the microphone module 600 comprises an overmold 603. This overmold 603 may cover or encapsulate the side walls of the package body 101 and the side walls of the micro-electro-mechanical microphone chip 103.

The microphone module 600 may comprise a lid 601 that may be similar to the lid 301 of FIG. 3 and the lid 501 of FIG. 5. The lid 601 may have an acoustic aperture 602 similar to acoustic apertures 302, 502. The lid 601 may be a separate element that may be arranged on top of the micro-electro-mechanical microphone chip 103 and may be located adjacent to an overmold 603. The lid 601 may also form an integral part of the overmold 603. The concept of applying an overmold 601 to cover side walls of the package body 101 and the side walls of the micro-electro-mechanical microphone chip 103 may be applied to all embodiments disclosed herein.

The microphone module disclosed herein may comprise various package types such as eWLP packages, QFN (quad flat no lead)-type packages with, e.g., a half-etch leadframe or another lead-frame based package or a laminate-based package, for instance ball grid array (BGA)-type packages. In each case, the used package body 101 may comprise the semiconductor chip 102 and the recess 105 as described above, wherein the semiconductor chip 102 may be embedded in the package body 101. The semiconductor chip 102 may, e.g., be positioned beneath the recess 105. That is, the outline of the semiconductor chip 102 may intersect or be framed by the outline of the recess 105 if viewed in vertical projection. In other words, the footprint of the semiconductor chip 102 may lie completely or at least partly within the outline of the recess 105.

The exemplary microphone module 700 as illustrated in FIG. 7 comprises a QFN-type package with half-etch leadframe 701. On top of this QFN-type package body 101, the micro-electro-mechanical microphone chip 103 may be arranged using the same techniques as described above.

In the exemplary microphone module 700, the semiconductor chip 102 may be arranged between a plurality of parts of the leadframe 701. The plurality of parts of the leadframe 701 may be exposed at the periphery of the package body 101. More specifically, the plurality of parts of the leadframe 701 may, e.g., be exposed at the lower surface of the package body 101, at a side surface thereof, or both. As illustrated in FIG. 7, the micro-electro-mechanical microphone chip 102 may be directly bonded to some of the parts of the leadframe 701. As such, no through-contacts 204 penetrating the package body 101 are needed in this embodiment.

Further, as shown in FIG. 7, the upper surface of the parts of the leadframe 701 may, e.g., have a curvature to form a trough-shaped depression 702.

The leadframe 701 with the semiconductor chip 102 placed between the plurality of parts thereof may be filled with an insulating material 704 such as, e.g., a polymer molding material or a polymer laminate. The recess 105 may be formed by the insulating material 704. According to an embodiment, the recess 105 may be formed to be aligned with the trough-shaped depression formed by the parts of the leadframe 701.

Prior to or concurrently with applying the insulating material, the semiconductor chip 102 may be electrically connected to the parts of the leadframe 701 via, e.g., bond wires 703 as exemplified in FIG. 7 or by other types of electrical connections such as, e.g., metal traces deposited on an insulating layer arranged over the plurality of parts of the leadframe 701 or deposited on the insulating material 704.

The embodiments as described in conjunction with FIGS. 3 to 6 may be combined with the embodiment as illustrated in FIG. 7. In particular, a lid may be added and/or an overmolding may be applied, etc.

In general, the embodiments of the microphone module as described herein may provide a small and compact module. In particular, compactness of the modules is promoted by embedding the semiconductor chip 102 in the package body 101 and by providing the acoustic back volume of the microphone (i.e. the recess 105, 403) over the semiconductor chip 102.

Several semiconductor chips 102 may be arranged in the module. Furthermore, according to an embodiment, all of the several semiconductor chips 102 are be embedded in the package body 101.

FIGS. 8 to 11 illustrate process stages of an exemplary method of producing a microphone module 100. The stages of production illustrated in FIGS. 8 to 11 may be understood as simplifications, since further steps may be used which are not depicted in these figures. Furthermore, some of the steps illustrated in FIGS. 8 to 11 may be omitted or substituted by other process steps. In particular, although the steps as described in connection with FIGS. 8 to 11 are performed on wafer level (or artificial wafer level), the manufacturing may also be performed on chip level. Thus, an assembly of wafer to wafer, in particular semiconductor wafer to artificial wafer, will be described in the following. However, an assembly of chip to wafer, in particular micro-electro-mechanical microphone chip 103 to artificial wafer, or chip to chip, in particular micro-electro-mechanical microphone chip 103 to package body 101, is also possible.

Some or all processes described herein may be performed on wafer level as exemplified in FIGS. 8 to 11. Here, wafer level means that the assembled microphone modules are still integral, i.e. not separated into single microphone modules. An exemplary processing on wafer level will now be described in greater detail.

As may be seen in FIG. 8, two wafers 801 and 803 may be used. Wafer 801 may be a micro-electro-mechanical systems (MEMS) wafer comprising an array of micro-electro-mechanical microphone structures 802, each having an electro-mechanical element 104 such as, e.g., one or more membranes 206, 207, see FIG. 2. The wafer 801 may e.g. be a silicon wafer. The electro-mechanical elements 104 may be manufactured by micro-mechanical machining techniques, e.g. by using masking techniques, lithography, etching, milling, etc.

Further, an electrical interconnect may have been applied to the micro-electro-mechanical systems (MEMS) wafer 801. The electrical interconnect may include, e.g., conducting deposits 202 such as, solder deposits or studbumps, and may include, e.g., an internal wiring interconnecting the electronic element configured to generate an electrical signal modulated according to the actuation of the electro-mechanical element 104 to the conducting deposits 202. Thus, the MEMS wafer 801 may already be fully processed at that stage of the process.

Wafer 803, also referred to as “artificial wafer” or “reconfigured wafer,” may comprise an array of integral package bodies 101. Wafer 803 may be manufactured in eWLP technology. Each package body 101 comprises at least one semiconductor chip 102 and one recess 105. The recesses 105 may be formed, e.g., during the process of forming the wafer 803 or by machining the upper surface 106 of the formed wafer 803.

Forming the wafer 803 may comprise singulating a semiconductor wafer (not shown) into a plurality of semiconductor chips 102. The plurality of semiconductor chips 102 may then be placed on a temporary carrier (not shown) in a spaced-apart relationship. The temporary carrier may have, e.g., a flat surface, and an adhesive tape, e.g., a double sided sticky tape, and may be laminated onto this surface of the temporary carrier. The semiconductor chips 102 and, e.g., additional components such as, passive components (e.g. capacities, inductors, resistors, antennas) of the microphone module to be fabricated may be placed on this adhesive tape. The semiconductor chips 102 may be arranged over the temporary carrier with their surfaces containing the chip contact pads facing the temporary carrier. In this case, the lower chip surfaces and chip contact pads may be in direct contact with the adhesive tape. Alternatively, a glue material or any other adhesive material or mechanical securing means (such as a clamping device or a vacuum generator) may be associated with the temporary carrier and used for fixing the semiconductor chips 102 and, e.g., additional component to the temporary carrier.

To package the semiconductor chips 102, the semiconductor chips 102 are encapsulated with an encapsulation material forming an encapsulant 804 as illustrated in FIG. 8. The encapsulation material may cover the upper main surfaces of the semiconductor chips 102 and also the side faces of the semiconductor chips 102. The gaps between the semiconductor chips 102 (and, e.g., other components) are also filled with the encapsulation material. For example, the encapsulation material may be a duroplastic or thermosetting mold material. The encapsulation material may be based on an epoxy material and may contain a filling material consisting of small particles of glass (SiO₂) or other electrically insulating mineral filler materials like Al₂O₃ or organic filler materials. The encapsulation material may be based on a polymer material. After curing, the encapsulation material provides stability to the array of semiconductor chips 102 embedded in the encapsulant, i.e. the artificial wafer 803.

Various techniques may be employed to cover the semiconductor chips 102 with the encapsulation material. For instance, the encapsulation material (e.g. mold material) may be applied by compression molding, injection molding, granulate molding, powder molding or liquid molding.

In a compression molding process, the liquid encapsulation material may be dispensed into an open lower mold, half of which the temporary carrier (not shown) forms the bottom. Then, after dispensing the liquid encapsulation material, an upper mold half is moved down and spreads out the liquid encapsulation material until a cavity between the temporary carrier forming the bottom of the lower mold half and the upper mold half is completely filled. This process may be accompanied by the application of heat and pressure. After curing, the encapsulation material is rigid and forms the encapsulant or artificial wafer 803. The larger the lateral size of the artificial wafer 803 and the number of embedded semiconductor chips 102, the more cost efficient the process will typically be.

The array of recesses 105 may be formed by a moldtool having an upper mold half which is equipped with an array of protrusions. The array of protrusions are designed to form the array of recesses, and the positions of the semiconductor chips 102 placed on the temporary carrier are aligned to the array of protrusions.

Further or alternatively, a polymer laminate material may be used to encapsulate the semiconductor chips 102 and to form the encapsulant 804. The polymer laminate material may have the shape of an electrically insulating foil or sheet, which is laminated on top of the semiconductor chips 102 as well as the temporary carrier. Heat and pressure may be applied for a suitable time to attach the polymer foil or sheet to the underlying structure. The gaps between the semiconductor chips 102 are also filled with the polymer laminate material. The polymer laminate material may, for example, be a prepreg (short for preimpregnated fibers) that is a combination of a fiber mat, e.g., glass or carbon fibers, and a resin, e.g., a duroplastic material. Prepreg materials are usually used to manufacture PCBs (printed circuit boards). Prepreg materials are bi-stage materials that are flexible when applied over the semiconductor chips 102 and harden during a heat-treatment. For the lamination of the prepreg, the same or similar process steps can be used as in PCB manufacturing.

The electrical interconnect of the package body 101 may also be generated on wafer level, i.e. before singulating the artificial wafer 803 into single package bodies 101. The electrical interconnect may comprise, e.g., the electrical redistribution structure 205, the through-contacts 204 and the shielding layer 201.

The through-contacts 204 may be generated by forming through holes and filling them with a conducting material, e.g. metal. The through holes may be fabricated as through mold vias during molding, or may be generated after molding using machining techniques such as drilling. The conducting material may be applied, e.g., through galvanization or other plating techniques. The shielding layer 201 may be applied as a selective top metallization e.g., by using lamination, plating or deposition techniques.

The semiconductor chips 102 encapsulated in the encapsulant 804 are released from the temporary carrier. The adhesive tape may feature thermo-release properties that allow the removal of the adhesive tape during a heat-treatment.

After the release of the encapsulant 804 from the temporary carrier, the electrical redistribution structure 205 may be applied to the lower, flat surface of the wafer 803. The electrical redistribution structure 205 may comprise one or more structured conductive layers separated by polymer layers and interconnected by vias. It may be generated by thin-film techniques using structuring methods such as, e.g., lithography, etching, etc.

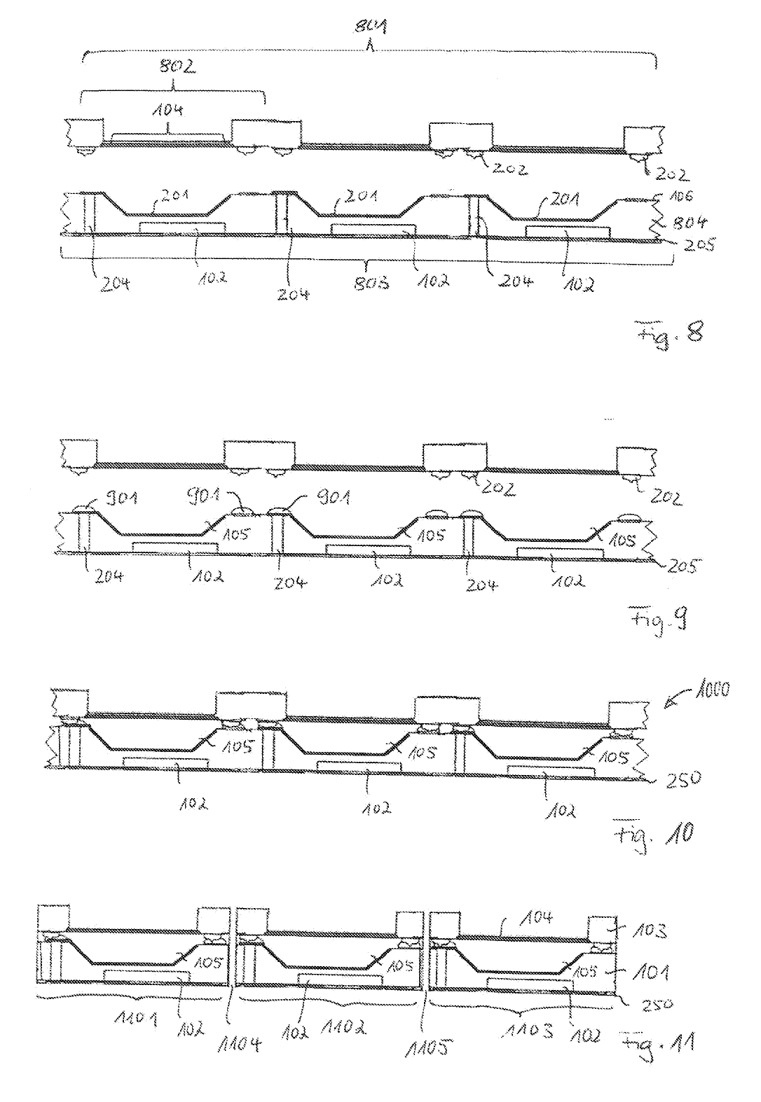

In a next step as shown in FIG. 9, connection means 901 may be deposited on the wafer 803. The connection means may be for instance anisotropic conductive paste, which may be deposited by printing, dispensing, or other techniques. The connections means 901 may be identical to the material forming the acoustic seal 203 as described above.

In a next step, the two wafers 801 and 803 may be bonded to produce a single wafer compound device 1000. The bonding may comprise the formation of an electrical interconnect as well as an acoustic seal 203 for each package body 101 and micro-electro-mechanical microphone chip 103. The bonding may be performed by applying energy (e.g., heat, radiation) and pressure to the two wafers. The acoustic seal 203 and the electrical interconnect may be generated in a sequential manner or concurrently within the same process step. The acoustic seal 203 and the electrical interconnect may be provided by different means (e.g., a nonconductive paste (NCP) and studbumps) or by the same means—for example, an anisotropic conductive paste (ACP) may provide for both the acoustic seal 203 and the electrical interconnect.

The bonding as shown in FIG. 10 is performed on wafer level. However, the bonding step may also be performed as bonding of single micro-electro-mechanical microphone chips 103 to artificial wafer 803 or as bonding of the MEMS wafer 801 to single package bodies 101 arranged in an array pattern or as bonding of single micro-electro-mechanical microphone chips 103 to single package bodies 101.

After the bonding, the microphone modules 1101, 1102, 1103 may be singulated. Singulation may be performed by using a dicing technique such as, e.g., blade dicing (sawing), laser dicing, etching, plasma etching, etc. Multi step dicing using different dicing techniques is also possible. According to an embodiment, the MEMS wafer 801 may, e.g., be singulated by using etching techniques whereas the package body wafer 803 may, e.g., be singulated by sawing.

The microphone modules 1101, 1102, 1103 are singulated along dicing streets 1104, 1105 between the microphone modules, as illustrated in FIG. 11, such that each microphone module 1101, 1102, 1103 comprises all necessary elements. Dicing streets 1104, 1105 may be arranged in rows and columns, although only a row of three components is shown. After dicing, the microphone modules 1101, 1102, 1103 may be ready for use.

Although specific embodiments have been illustrated and described herein, those of ordinary skill in the art will appreciate that that a variety of alternate and/or equivalent implementations may be substituted for the specific embodiments shown and described without departing from the scope of the present invention. This application is intended to cover any adaptations or variations of the specific embodiments discussed herein. Therefore, it is intended that this invention be limited only by the claims and the equivalents thereof.

What is claimed is:

1. A microphone module, comprising:
a package body having a recess on an upper surface;
a semiconductor chip embedded in the package body; and
a micro-electro-mechanical microphone chip comprising an electro-mechanical element arranged over the recess and electrically connected to the semiconductor chip.

2. The microphone module of claim 1, wherein the recess forms an acoustic back volume of the micro-electro-mechanical microphone chip.

3. The microphone module of claim 1, wherein the semiconductor chip is an application specific integrated circuit.

4. The microphone module of claim 1, wherein the package body comprises through-contacts for electrically connecting the micro-electro-mechanical microphone chip to the semiconductor chip.

5. The microphone module of claim 1, wherein the semiconductor chip is positioned beneath the recess.

6. The microphone module of claim 1, further comprising:
an electrical redistribution structure arranged at a bottom surface of the package body.

7. The microphone module of claim 1, further comprising:
an acoustic seal arranged between the micro-electro-mechanical microphone chip and the package body.

8. The microphone module of claim 1, further comprising:
a shielding layer arranged on the upper surface of the package body.

9. The microphone module of claim 1, wherein the package body and the micro-electro-mechanical microphone chip have an equal lateral dimension in at least one lateral direction.

10. The microphone module of claim 1, wherein the micro-electro-mechanical microphone chip is arranged at least partially within the recess of the package body.

11. The microphone module of claim 1, wherein the micro-electro-mechanical microphone chip is flip-chip mounted to the package body.

12. The microphone module of claim 1, further comprising:
a lid arranged on top of the micro-electro-mechanical microphone chip.

13. A microphone module assembly, comprising:
an encapsulant comprising an array of recesses on an upper surface;
an array of semiconductor chips embedded in the encapsulant, wherein each semiconductor chip is associated with a recess; and
an array of micro-electro-mechanical microphone structures, wherein each micro-electro-mechanical microphone structure comprises an electro-mechanical element arranged over one of the recesses and is electrically connected to the semiconductor chip associated with the respective recess.

14. The microphone module assembly of claim 13, wherein the array of micro-electro-mechanical microphone structures is formed on a semiconductor wafer.

15. The microphone module assembly of claim 13, wherein the array of micro-electro-mechanical microphone structures is designed as an array of single micro-electro-mechanical microphone chips, and wherein each micro-electro-mechanical microphone chip contains one micro-electro-mechanical microphone structure.

16. A method of producing a microphone module, comprising:
providing a package body having a recess on an upper surface and comprising a semiconductor chip;
providing a micro-electro-mechanical microphone chip comprising an electro-mechanical element;
arranging the micro-electro-mechanical microphone chip over the upper surface of the package body; and
electrically connecting the micro-electro-mechanical microphone chip to the package body such that the recess forms an acoustic back volume of a micro-electro-mechanical microphone.

17. The method of claim 16, further comprising
providing an acoustic seal between the package body and the micro-electro-mechanical microphone chip.

18. A method of producing a microphone module, comprising:
forming an encapsulant having an array of recesses on an upper surface thereof and an array of semiconductor chips embedded therein;
arranging an array of micro-electro-mechanical microphone structures over the encapsulant, wherein each micro-electro-mechanical microphone structure comprises an electro-mechanical element arranged over a recess;
electrically connecting each of the plurality of micro-electro-mechanical microphone structures to a semiconductor chip associated with the respective recess; and
separating the encapsulant into single package bodies, each package body comprising one of the recesses and one of the semiconductor chips.

19. The method of claim 18, further comprising:
forming the array of micro-electro-mechanical microphone structures on a semiconductor wafer before arranging the array; and
separating the semiconductor wafer into single micro-electro-mechanical microphone chips after arranging the array.

20. The method of claim 18, further comprising:
forming the array of micro-electro-mechanical microphone structures on a semiconductor wafer before arranging the array; and
separating the semiconductor wafer into single chips before arranging the array.
